(19) United States
(12) Patent Application Publication
(10) Pub. No.: US 2004/0161710 A1
(43) Pub. Date: Aug. 19, 2004

(54) Pattern formation method

(75) Inventors: Masayuki Endo, Osaka (JP); Masaru Sasago, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/735,688

(22) Filed: Dec. 16, 2003

(30) Foreign Application Priority Data
Feb. 17, 2003 (JP) 2003-037917

(51) Int. Cl. G03F 7/26

(52) U.S. Cl. 430/322; 430/270.1

(57) ABSTRACT

A pattern formation method of this invention includes the steps of forming a resist film of a chemically amplified resist material and forming a resist pattern by developing the resist film with an alkaline developer after irradiating, through a mask having a desired pattern, the resist film with exposing light having a light component entering the resist film at the Brewster's angle. A thickness reduction ratio of the resist pattern to the resist film is 5% or less.

### BACKGROUND OF THE INVENTION

The present invention relates to a pattern formation method for use in fabrication process and the like for semiconductor devices.

In accordance with the increased degree of integration of semiconductor integrated circuits and downsizing of semiconductor devices, there are increasing demands for further rapid development of lithography technique.

Currently, pattern formation is carried out through photolithography using exposing light of a mercury lamp, KrF excimer laser, ArF excimer laser or the like. With respect to an exposure system, attempts have been earnestly made to shorten the wavelength of exposing light and increase the NA (numerical aperture) of a reduction projection lens.

In particular, a variety of studies are being made to increase the NA. The NA is currently approximately 0.7 and is expected to be 0.9 or more in the future.

Now, a method for forming a resist pattern by selectively irradiating a resist film of a conventional chemically amplified resist material with exposing light with NA of 0.9 or more will be described with reference to FIGS. 9A through 9D.

First, a chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 35 mol %:65 mol %) | | |
| Acid generator: N-(trifluoromethylsulfonyloxy)phthalimide | 0.04 | g |
| Solvent: propylene glycol monomethyl ether acetate | 20 | g |

Next, as shown in FIG. 9A, the aforementioned chemically amplified resist material is applied on a substrate 1 so as to form a resist film 2 with a thickness of 0.4 μm.

Then, as shown in FIG. 9B, pattern exposure is carried out by irradiating the resist film 2 with KrF excimer laser 3 with NA of 0.92 through a photomask 4.

Thereafter, as shown in FIG. 9C, the substrate 1 is baked with a hot plate at a temperature of 100° C. for 60 seconds. Thus, an exposed portion 2a of the resist film 2 becomes soluble in an alkaline developer because an acid is generated from the acid generator therein while an unexposed portion 2b of the resist film 2 remains insoluble in an alkaline developer because no acid is generated from the acid generator therein.

Next, the resultant resist film 2 is developed with a 2.38 wt % tetramethylammonium hydroxide developer (alkaline developer). In this manner, a resist pattern 5 made of the unexposed portion 2b of the resist film 2 and having a line width of 0.13 μm can be obtained as shown in FIG. 9D.

However, as shown in FIG. 9D, the resist pattern 5 is largely reduced in its thickness and is in a defective shape. When the resist pattern 5 in such a defective shape is used for etching a target film, the resultant pattern is also in a defective shape, which disadvantageously lowers the productivity and the yield in the fabrication process for semiconductor devices.

It has been proposed that when the NA of exposing light exceeds 0.9, the polarization effect is caused and hence the contrast of light entering a resist film is lowered on the contrary (T. A. Brunner et al., “High-NA lithographic imagery at Brewster's angle”, Proc. SPIE, Vol. 4691, 1(2002)).

The Brewster's angle θ described in this literature is defined to have a value expressed as tan θ=n assuming that light having entered the surface of a substance (such as a resist film) with a refractive index n and being reflected by the surface is localized in a direction completely parallel to the surface of the substance (See FIG. 10).

According to the literature, when an angle θ₁ based on which the NA of a reduction projection lens is determined (namely, NA=sinθ₁; See FIG. 11) exceeds the Brewster's angle θ, a phenomenon designated as the polarization effect, namely, a phenomenon that the contrast of light entering a resist film is lowered, occurs.

It seems that since the light contrast of the exposing light used for irradiating the resist film 2 is lowered due to this polarization effect, the resist pattern 5 is in a defective shape.

### SUMMARY OF THE INVENTION

In consideration of the aforementioned conventional problem, an object of the invention is forming a resist pattern in a good shape even when the resist pattern is formed by using exposing light having a light component entering a resist film at the Brewster's angle.

In order to achieve the object, according to the invention, the lowering of the contrast of exposing light caused when the exposing light for irradiating a resist film has a light component entering the resist film at the Brewster's angle is compensated by increasing solubility contrast of the resist film. Herein, the solubility contrast of a resist film is defined as (a dissolving rate of an exposed portion of a resist film)/(a dissolving rate of an unexposed portion of the resist film) in a positive resist film or as (a dissolving rate of an unexposed portion of a resist film)/(a dissolving rate of an exposed portion of the resist film) in a negative resist film.

Accordingly, in the case where a positive chemically amplified resist material is used, the solubility contrast of a resist film can be increased by increasing the dissolving rate of an exposed portion of the resist film or lowering the dissolving rate of an unexposed portion of the resist film. In the case where a negative chemically amplified resist material is used, the solubility contrast of a resist film can be increased by increasing the dissolving rate of an unexposed portion of the resist film or lowering the dissolving rate of an exposed portion of the resist film.

The present invention was devised on the basis of this finding, and is specifically practiced as follows:

The first pattern formation method of this invention includes the steps of forming a resist film of a chemically amplified resist material; and forming a resist pattern by developing the resist film with an alkaline developer after irradiating, through a mask having a desired pattern, the resist film with exposing light having a light component entering the resist film at the Brewster's angle, and a thickness reduction ratio of the resist pattern to the resist film is 5% or less.

In the first pattern formation method, when the chemically amplified resist material is a positive type, the dissolving rate of an unexposed portion of the resist film can be lowered, and when it is a negative type, the dissolving rate of an exposed portion of the resist film can be lowered. Therefore, in either case, the solubility contrast of the resist film can be improved. Accordingly, the lowering of the contrast of the exposing light caused when the exposing light has a light component entering the resist film at the Brewster's angle can be compensated by the improved solubility contrast of the resist film, so that the resist pattern can be formed in a good shape.

In the first pattern formation method, the chemically amplified resist material is preferably a positive type, and a protection ratio that is a ratio of a polymer protected by a protecting group in an alkali-soluble polymer included in the chemically amplified resist material is preferably 50% or more.

When the ratio of the polymer protected by the protecting group in the alkali-soluble polymer included in the positive chemically amplified resist material (namely, the protection ratio) is thus 50% or more, the dissolving rate of an unexposed portion of the positive resist film can be lowered. Accordingly, the thickness reduction ratio of the resist pattern to the resist film can be suppressed to 5% or less.

In this case, the protecting group can be a t-butyl group or a t-butyloxycarbonyl group.

In the first pattern formation method, the chemically amplified resist material is preferably a positive type, and an acid generator included in the chemically amplified resist material is preferably an onium salt.

When an onium salt with high volatility is thus used as the acid generator included in the positive chemically amplified resist material, the dissolving rate of an unexposed portion of the positive resist film can be lowered. Accordingly, the thickness reduction ratio of the resist pattern to the resist film can be suppressed to 5% or less.

In this case, the onium salt can be triphenylsulfonium trifluoromethanesulfonic acid, triphenylsulfonium nonafluorobutanesulfonic acid or diphenyliodonium trifluoromethanesulfonic acid.

In the first pattern formation method, the chemically amplified resist material is preferably a positive type, and the pattern formation method preferably further includes, between the step of forming a resist film and the step of forming a resist pattern, a step of forming, in a surface portion of the resist film, an insoluble layer that is insoluble in the alkaline developer.

When the insoluble layer is thus formed in the surface portion of the positive chemically amplified resist film, the dissolving rate of an unexposed portion of the positive resist film can be lowered. Accordingly, the thickness reduction ratio of the resist pattern to the resist film can be suppressed to 5% or less. In this case, although the insoluble layer is formed also in a surface portion of an exposed portion of the resist film, this insoluble layer is eliminated while the exposed portion of the resist film is dissolved in the alkaline developer, and hence, the dissolving rate of the exposed portion of the resist film is not substantially changed.

In this case, the insoluble layer is preferably formed by supplying an alkaline aqueous solution onto the resist film.

Thus, the insoluble layer can be formed in the surface portion of the resist film.

The alkaline aqueous solution used for forming the insoluble layer can be a tetramethylammonium hydroxide aqueous solution, a tetraethylammonium hydroxide aqueous solution, a tetra-n-butylammonium hydroxide aqueous solution or a choline aqueous solution.

The second pattern formation method of this invention includes the steps of forming a resist film of a positive chemically amplified resist material; and forming a resist pattern by developing the resist film with an alkaline developer after irradiating, through a mask having a desired pattern, the resist film with exposing light having a light component entering the resist film at the Brewster's angle, and the chemically amplified resist material includes a base polymer for generating carboxylic acid through irradiation with light.

In the second pattern formation method, when the positive chemically amplified resist film is irradiated with the exposing light, carboxylic acid, that is, a strong acid, is generated in an exposed portion of the resist film, thereby increasing the dissolving rate of the exposed portion of the resist film. Therefore, the solubility contrast of the resist film can be improved. Accordingly, the lowering of the contrast of the exposing light caused when the exposing light has a light component entering the resist film at the Brewster's angle can be compensated by the improved solubility contrast of the resist film. As a result, the resist pattern can be formed in a good shape.

In the second pattern formation method, the chemically amplified resist material preferably includes a dissolution inhibitor for generating carboxylic acid through irradiation with light.

Thus, the dissolving rate of the exposed portion of the positive resist film can be further increased, so that the solubility contrast of the resist film can be further improved.

The third pattern formation method of this invention includes the steps of forming a resist film of a positive chemically amplified resist material; and forming a resist pattern by developing the resist film with an alkaline developer after irradiating, through a mask having a desired pattern, the resist film with exposing light having a light component entering the resist film at the Brewster's angle, and the chemically amplified resist material includes a dissolution inhibitor for generating carboxylic acid through irradiation with light.

In the third pattern formation method, when the positive chemically amplified resist film is irradiated with the exposing light, carboxylic acid, that is, a strong acid, is generated in an exposed portion of the resist film, thereby increasing the dissolving rate of the exposed portion of the resist film. Therefore, the solubility contrast of the resist film can be improved. Accordingly, the lowering of the contrast of the exposing light caused when the exposing light has a light component entering the resist film at the Brewster's angle can be compensated by the improved solubility contrast of the resist film. As a result, the resist pattern can be formed in a good shape.

In the second or third pattern formation method, the carboxylic acid generated from the base polymer or the dissolution inhibitor can be acrylic acid, methacrylic acid or α-trifluoromethylacrylic acid.

The fourth pattern formation method of this invention includes the steps of forming a resist film of a positive chemically amplified resist material; and forming a resist pattern by developing the resist film with an alkaline developer after irradiating, through a mask having a desired pattern, the resist film with exposing light having a light component entering the resist film at the Brewster's angle, and the chemically amplified resist material includes a base polymer for generating sulfonic acid through irradiation with light.

In the fourth pattern formation method, when the positive chemically amplified resist film is irradiated with the exposing light, sulfonic acid, that is, a strong acid, is generated in an exposed portion of the resist film, thereby increasing the dissolving rate of the exposed portion of the resist film. Therefore, the solubility contrast of the resist film can be improved. Accordingly, the lowering of the contrast of the exposing light caused when the exposing light has a light component entering the resist film at the Brewster's angle can be compensated by the improved solubility contrast of the resist film. As a result, the resist pattern can be formed in a good shape.

In the fourth pattern formation method, the chemically amplified resist material preferably includes a dissolution inhibitor for generating sulfonic acid through irradiation with light.

Thus, the dissolving rate of the exposed portion of the positive resist film can be further increased, and hence, the solubility contrast of the resist film can be further improved.

The fifth pattern formation method of this invention includes the steps of forming a resist film of a positive chemically amplified resist material; and forming a resist pattern by developing the resist film with an alkaline developer after irradiating, through a mask having a desired pattern, the resist film with exposing light having a light component entering the resist film at the Brewster's angle, and the chemically amplified resist material includes a dissolution inhibitor for generating sulfonic acid through irradiation with light.

In the fifth pattern formation method, when the positive chemically amplified resist film is irradiated with the exposing light, sulfonic acid, that is, a strong acid, is generated in an exposed portion of the resist film, thereby increasing the dissolving rate of the exposed portion of the resist film. Therefore, the solubility contrast of the resist film can be improved. Accordingly, the lowering of the contrast of the exposing light caused when the exposing light has a light component entering the resist film at the Brewster's angle can be compensated by the improved solubility contrast of the resist film. As a result, the resist pattern can be formed in a good shape.

In the fourth or fifth pattern formation method, the sulfonic acid generated from the base polymer or the dissolution inhibitor can be vinylsulfonic acid or styrenesulfonic acid.

The sixth pattern formation method of this invention includes the steps of forming a resist film of a positive chemically amplified resist material; and forming a resist pattern by developing the resist film with an alkaline developer after irradiating, through a mask having a desired pattern, the resist film with exposing light having a light component entering the resist film at the Brewster's angle, and the chemically amplified resist material includes an acid.

In the sixth pattern formation method, when the positive chemically amplified resist film is irradiated with the exposing light, the dissolving rate of an exposed portion of the resist film is increased. Therefore, the solubility contrast of the resist film can be improved. Accordingly, the lowering of the contrast of the exposing light caused when the exposing light has a light component entering the resist film at the Brewster's angle can be compensated by the improved solubility contrast of the resist film. As a result, the resist pattern can be formed in a good shape.

In the sixth pattern formation method, the acid included in the chemically amplified resist material can be acetic acid, acrylic acid or formic acid.

In each of the first through sixth pattern formation methods, the exposing light can be UV, KrF excimer laser, ArF excimer laser, F₂ laser, ArKr laser, Ar₂ laser, Kr₂ laser or extreme UV.

### BRIEF DESCRIPTION OF THE DRAWINGS

FIGS. 1A, 1B, 1C and 1D are cross-sectional views for showing procedures in a pattern formation method according to Embodiment 1 of the invention;

FIGS. 2A, 2B, 2C and 2D are cross-sectional views for showing procedures in a pattern formation method according to Embodiment 2 of the invention;

FIGS. 3A, 3B, 3C, 3D and 3E are cross-sectional views for showing procedures in a pattern formation method according to Embodiment 3 of the invention;

FIGS. 4A, 4B, 4C and 4D are cross-sectional views for showing procedures in a pattern formation method according to Embodiment 4 of the invention;

FIGS. 5A, 5B, 5C and 5D are cross-sectional views for showing procedures in a pattern formation method according to Embodiment 5 of the invention;

FIGS. 6A, 6B, 6C and 6D are cross-sectional views for showing procedures in a pattern formation method according to Embodiment 6 of the invention;

FIGS. 7A, 7B, 7C and 7D are cross-sectional views for showing procedures in a pattern formation method according to Embodiment 7 of the invention;

FIGS. 8A, 8B, 8C and 8D are cross-sectional views for showing procedures in a pattern formation method according to Embodiment 8 of the invention;

FIGS. 9A, 9B, 9C and 9D are cross-sectional views for showing procedures in a conventional pattern formation method;

FIG. 10 is a diagram for explaining the Brewster's angle; and

FIG. 11 is a diagram for explaining the polarization effect.

### DETAILED DESCRIPTION OF THE INVENTION

Embodiment 1

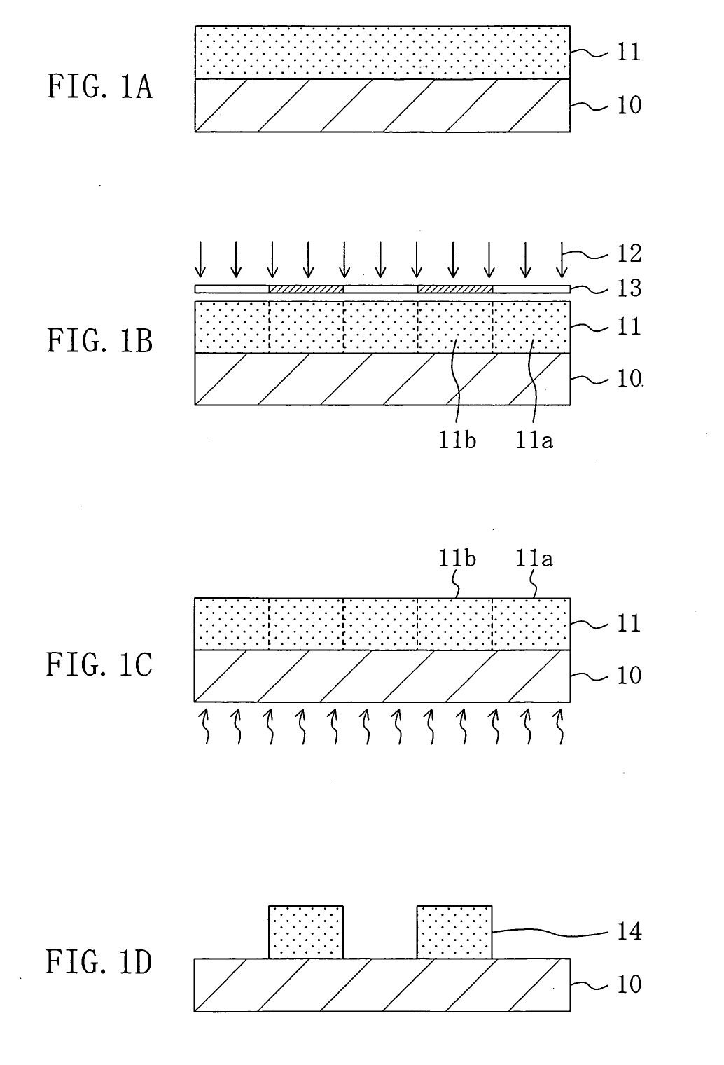

A pattern formation method according to Embodiment 1 of the invention will now be described with reference to FIGS. 1A through 1D.

First, a positive chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 60 mol %:40 mol %) | | |
| Acid generator: N-(trifluoromethylsulfonyloxy)phthalimide | 0.04 | g |
| Solvent: propylene glycol monomethyl ether acetate | 20 | g |

Next, as shown in FIG. 1A, the aforementioned chemically amplified resist material is applied on a substrate 10 so as to form a resist film 11 with a thickness of 0.4 μm.

Then, as shown in FIG. 1B, pattern exposure is carried out by irradiating the resist film 11 with KrF excimer laser 12 with NA of 0.92 through a photomask 13. In this case, since the NA is 0.92, the exposing light of the KrF excimer laser 12 has a light component entering the resist film 11 at the Brewster's angle.

Thereafter, as shown in FIG. 1C, the substrate 10 is baked with a hot plate at a temperature of 110° C. for 60 seconds. Thus, an exposed portion 11a of the resist film 11 becomes soluble in an alkaline developer because an acid is generated from the acid generator therein while an unexposed portion 11b of the resist film 11 remains insoluble in an alkaline developer because no acid is generated from the acid generator therein.

Next, the resultant resist film 11 is developed with a 2.38 wt % tetramethylammonium hydroxide developer (alkaline developer). In this manner, a resist pattern 14 made of the unexposed portion 11b of the resist film 11 and having a line width of 0.13 μm can be formed in a good shape as shown in FIG. 1D.

In Embodiment 1, a protection ratio, that is, a ratio of a polymer protected by a protecting group in an alkali-soluble polymer included in the chemically amplified resist material, is 60%, namely exceeds 50%, and therefore, a thickness reduction ratio of the resist pattern 14 to the resist film 11 is 5% or less. Accordingly, the dissolving rate of the unexposed portion 11b of the resist film 11 made from the positive chemically amplified resist material can be lowered, so that the solubility contrast of the resist film 11 can be improved.

As a result, according to Embodiment 1, the lowering of the contrast of the exposing light derived from the polarization effect caused through irradiation with the exposing light having a light component entering the resist film 11 at the Brewster's angle can be compensated by the improved solubility contrast of the resist film 11, so that the resist pattern 14 can be formed in a good shape.

Although a t-butyloxycarbonyl group is used as the protecting group in Embodiment 1, a t-butyl group may be used instead.

Although the positive chemically amplified resist material is used in Embodiment 1, a negative chemically amplified resist material may be used instead. In this case, the dissolving rate of an exposed portion of a resist film of the negative chemically amplified resist material can be lowered by setting the thickness reduction ratio of a resist pattern to the resist film to 5% or less, and thus, the solubility contrast of the resist film can be improved.

Embodiment 2

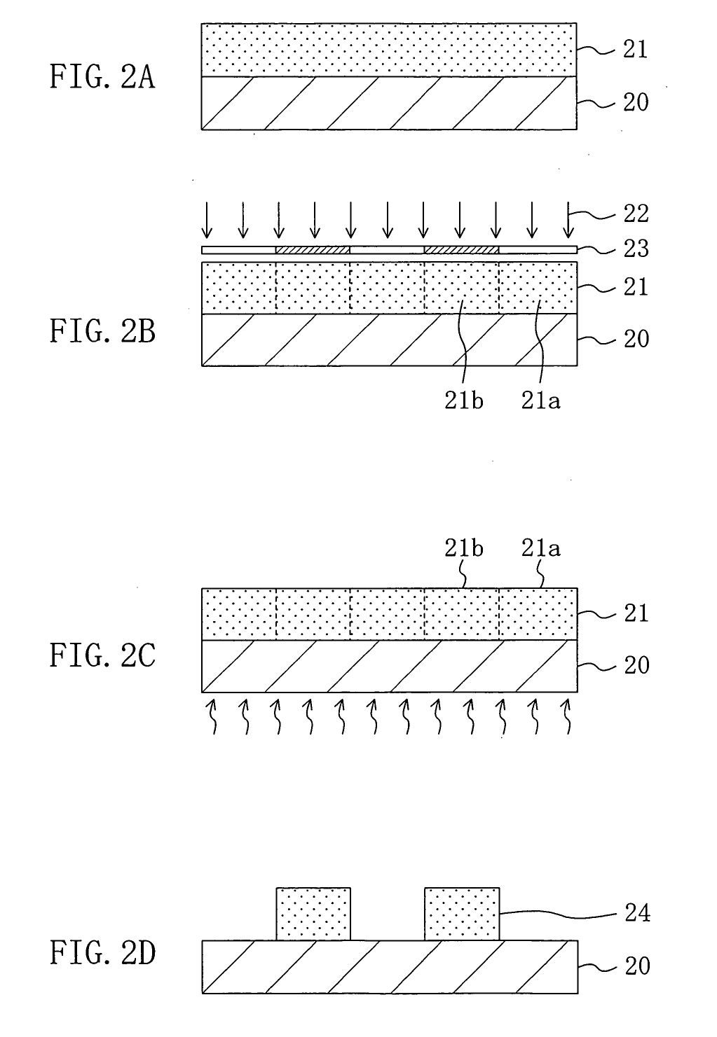

A pattern formation method according to Embodiment 2 of the invention will now be described with reference to FIGS. 2A through 2D.

First, a positive chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 40 mol %:60 mol %) | | |
| Acid generator: triphenylsulfonium | | |
| trifluoromethanesulfonic acid | 0.04 | g |
| Solvent: propylene glycol monomethyl ether acetate | 20 | g |

Next, as shown in FIG. 2A, the aforementioned chemically amplified resist material is applied on a substrate 20 so as to form a resist film 21 with a thickness of 0.4 μm.

Then, as shown in FIG. 2B, pattern exposure is carried out by irradiating the resist film 21 with KrF excimer laser 22 with NA of 0.92 through a photomask 23. In this case, since the NA is 0.92, the exposing light of the KrF excimer laser 22 has a light component entering the resist film 21 at the Brewster's angle.

Thereafter, as shown in FIG. 2C, the substrate 20 is baked with a hot plate at a temperature of 110° C. for 60 seconds. Thus, an exposed portion 21a of the resist film 21 becomes soluble in an alkaline developer because an acid is generated from the acid generator therein while an unexposed portion 21b of the resist film 21 remains insoluble in an alkaline developer because no acid is generated from the acid generator therein.

Next, the resultant resist film 21 is developed with a 2.38 wt % tetramethylammonium hydroxide developer (alkaline developer). In this manner, a resist pattern 24 made of the unexposed portion 21b of the resist film 21 and having a line width of 0.13 μm can be formed in a good shape as shown in FIG. 2D.

In Embodiment 2, the acid generator included in the chemically amplified resist material is an onium salt with high volatility. Accordingly, the dissolving rate of the unexposed portion 21b of the resist film 21 made from the positive chemically amplified resist material can be lowered, so that the thickness reduction ratio of the resist pattern 24 to the resist film 21 can be suppressed to approximately 4%.

As a result, according to Embodiment 2, the lowering of the contrast of the exposing light derived from the polarization effect caused through irradiation with the exposing light having a light component entering the resist film 21 at the Brewster's angle can be compensated by the improved solubility contrast of the resist film 21, so that the resist pattern 24 can be formed in a good shape.

Although triphenylsulfonium trifluoromethanesulfonic acid is used as the onium salt working as the acid generator in Embodiment 2, triphenylsulfonium nonafluorobutanesulfonic acid or diphenyliodonium trifluoromethanesulfonic acid may be used instead.

Embodiment 3

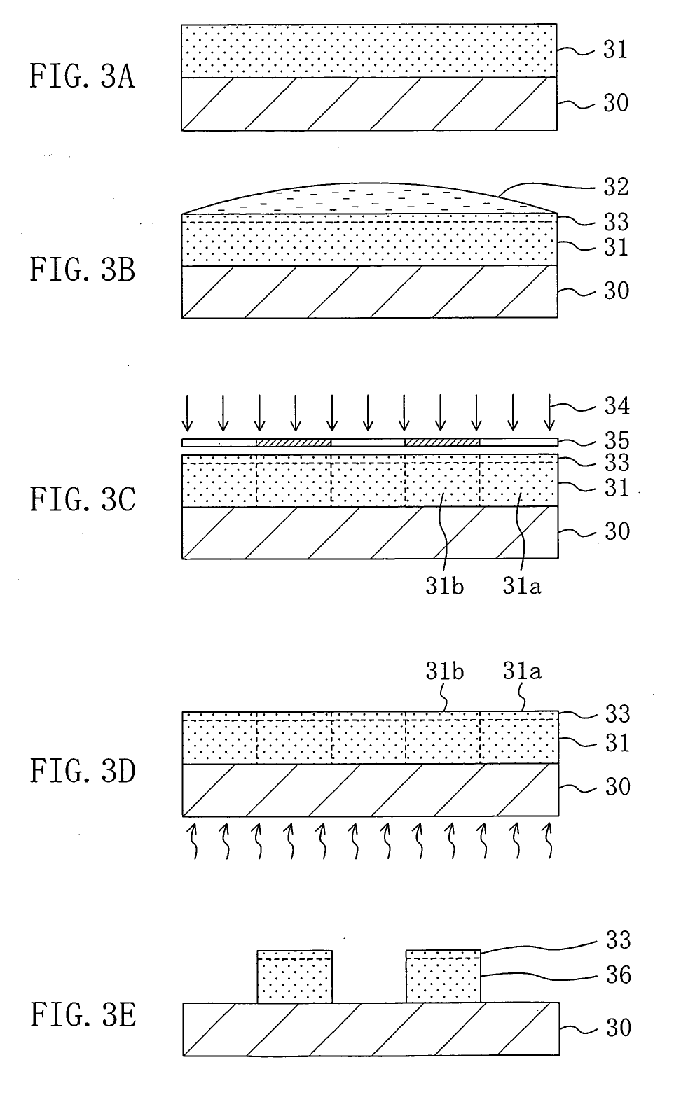

A pattern formation method according to Embodiment 3 of the invention will now be described with reference to FIGS. 3A through 3E.

First, a positive chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 35 mol %:65 mol %) | | |
| Acid generator: N-(trifluoromethylsulfonyloxy)phthalimide | 0.04 | g |
| Solvent: propylene glycol monomethyl ether acetate | 20 | g |

Next, as shown in FIG. 3A, the aforementioned chemically amplified resist material is applied on a substrate 30 so as to form a resist film 31 with a thickness of 0.4 μm.

Then, as shown in FIG. 3B, an alkaline aqueous solution of, for example, a 1.0 wt % tetramethylammonium hydroxide aqueous solution is supplied onto the resist film 31 for 60 seconds. Thus, an insoluble layer 33 insoluble in an alkaline developer is formed in a surface portion of the resist film 31.

Next, as shown in FIG. 3C, pattern exposure is carried out by irradiating the resist film 31 with KrF excimer laser 34 with NA of 0.92 through a photomask 35. In this case, since the NA is 0.92, the exposing light of the KrF excimer laser 34 has a light component entering the resist film 31 at the Brewster's angle.

Thereafter, as shown in FIG. 3D, the substrate 30 is baked with a hot plate at a temperature of 110° C. for 60 seconds. Thus, an exposed portion 31a of the resist film 31 becomes soluble in an alkaline developer because an acid is generated from the acid generator therein while an unexposed portion 31b of the resist film 31 remains insoluble in an alkaline developer because no acid is generated from the acid generator therein.

Next, the resultant resist film 31 is developed with a 2.38 wt % tetramethylammonium hydroxide developer (alkaline developer). In this manner, a resist pattern 36 made of the unexposed portion 31b of the resist film 31 and having a line width of 0.13 μm can be formed in a good shape as shown in FIG. 3E.

In Embodiment 3, the development with the alkaline developer is carried out after forming the insoluble layer 33 in the surface portion of the resist film 31 of the positive chemically amplified resist material. Accordingly, the dissolving rate of the unexposed portion 31b of the resist film 31 can be lowered, so that the thickness reduction ratio of the resist pattern 36 to the resist film 31 can be suppressed to 5% or less. In this case, although the insoluble layer 33 is formed also in a surface portion of the exposed portion 31a of the resist film 31, this insoluble layer 33 is eliminated while the exposed portion 31a of the resist film 31 is dissolved in the alkaline developer. Therefore, the dissolving rate of the exposed portion 31a of the resist film 31 is not substantially changed.

As a result, according to Embodiment 3, the lowering of the contrast of the exposing light derived from the polarization effect caused through irradiation with the exposing light having a light component entering the resist film 31 at the Brewster's angle can be compensated by the improved solubility contrast of the resist film 31, so that the resist pattern 36 can be formed in a good shape.

In Embodiment 3, the concentration of the tetramethylammonium hydroxide aqueous solution used as the alkaline aqueous solution is 1.0 wt % and the time for supplying the alkaline aqueous solution is 60 seconds. These conditions can be appropriately changed, and for example, in the case where the concentration of the tetramethylammonium hydroxide aqueous solution is 2.0 wt %, the time can be 20 seconds, and in the case where the concentration of the tetramethylammonium hydroxide aqueous solution is 0.5 wt %, the time can be 140 seconds.

Although the tetramethylammonium hydroxide aqueous solution is used as the alkaline aqueous solution in Embodiment 3, a tetraethylammonium hydroxide aqueous solution, a tetra-n-butylammonium hydroxide aqueous solution, a choline aqueous solution or the like may be used instead.

Embodiment 4

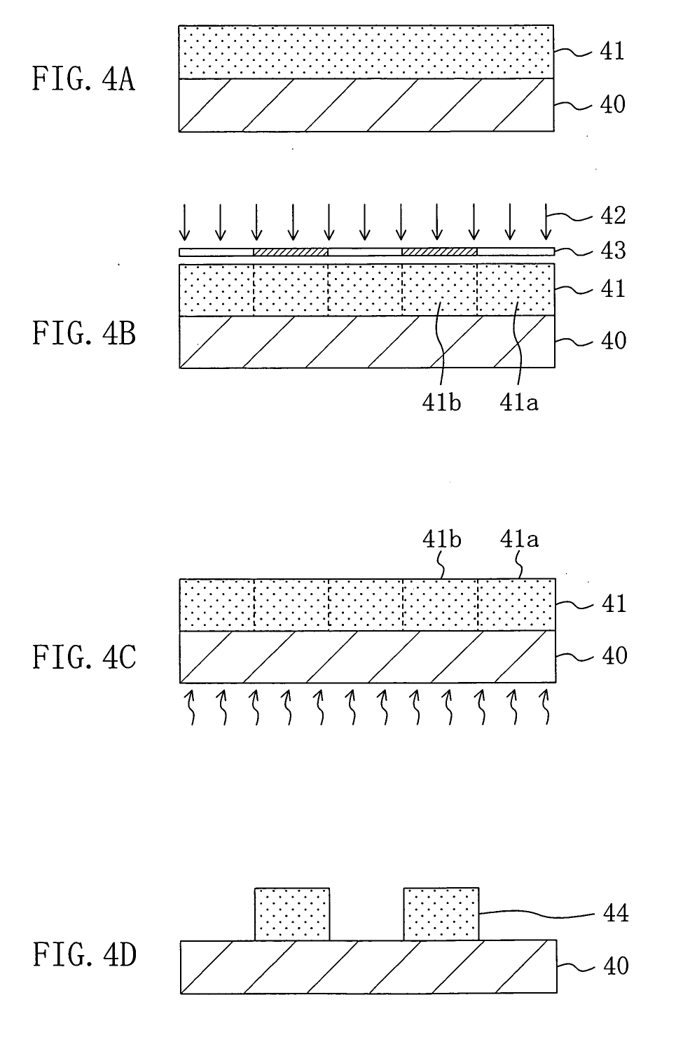

A pattern formation method according to Embodiment 4 of the invention will now be described with reference to FIGS. 4A through 4D.

First, a positive chemically amplified resist material having the following composition is prepared:

| | | |
|---|---|---|
| Base polymer: poly((2-methyl-adamantyl methacrylate) - | 2 | g |
| (mevalonic lactone methacrylate)) | | |
| (wherein 2-methyl-adamantyl methacrylate:mevalonic lactone | | |
| methacrylate = 40 mol %:60 mol %) | | |
| Dissolution inhibitor: t-butyl methacrylate | 0.30 | g |
| Acid generator: N-(trifluoromethylsulfonyloxy)succinimide | 0.035 | g |
| Solvent: propylene glycol monomethyl ether acetate | 20 | g |

Next, as shown in FIG. 4A, the aforementioned chemically amplified resist material is applied on a substrate 40 so as to form a resist film 41 with a thickness of 0.35 μm.

Then, as shown in FIG. 4B, pattern exposure is carried out by irradiating the resist film 41 with ArF excimer laser 42 with NA of 0.92 through a photomask 43. In this case, since the NA is 0.92, the exposing light of the ArF excimer laser 42 has a light component entering the resist film 41 at the Brewster's angle.

Thereafter, as shown in FIG. 4C, the substrate 40 is baked with a hot plate at a temperature of 110° C. for 60 seconds. Thus, an exposed portion 41a of the resist film 41 becomes soluble in an alkaline developer because an acid is generated from the acid generator therein while an unexposed portion 41b of the resist film 41 remains insoluble in an alkaline developer because no acid is generated from the acid generator therein.

Next, the resultant resist film 41 is developed with a 2.38 wt % tetramethylammonium hydroxide developer (alkaline developer). In this manner, a resist pattern 44 made of the unexposed portion 41b of the resist film 41 and having a line width of 0.11 μm can be formed in a good shape as shown in FIG. 4D.

In Embodiment 4, when the resist film 41 is irradiated with the exposing light of the ArF excimer laser 42, carboxylic acid, that is, a strong acid, is generated from the base polymer and the dissolution inhibitor in the exposed portion 41a of the resist film 41. Accordingly, the dissolving rate of the exposed portion 41a of the resist film 41 can be increased, so that the solubility contrast of the resist film 41 can be improved.

As a result, according to Embodiment 4, the lowering of the contrast of the exposing light derived from the polarization effect caused through irradiation with the exposing light having a light component entering the resist film 41 at the Brewster's angle can be compensated by the improved solubility contrast of the resist film 41, so that the resist pattern 44 can be formed in a good shape.

The base polymer used in Embodiment 4 for generating carboxylic acid through irradiation with light may be an ester of polyacrylic acid, polymethacrylic acid or poly(α-trifluoromethylacrylic acid). Specific examples, which do not limit the invention, are poly(t-butyl acrylate), poly(methoxymethyl acrylate), poly(ethoxymethyl acrylate), poly(2-methyl-2-adamantyl acrylate), poly(t-butyl methacrylate), poly(methoxymethyl methacrylate), poly(ethoxymethyl methacrylate), poly(2-methyl-2-adamantyl methacrylate), poly(t-butyl-α-trifluoromethyl acrylate), poly(methoxymethyl-α-trifluoromethyl acrylate), poly(ethoxymethyl-α-trifluoromethyl acrylate) and poly(2-methyl-2-adamantyl-α-trifluoromethyl acrylate).

Also, the dissolution inhibitor for generating carboxylic acid through irradiation with light may be an ester of acrylic acid, methacrylic acid or α-trifluoromethyl acrylic acid. Specific examples, which do not limit the invention, are t-butyl acrylate, methoxymethyl acrylate, ethoxymethyl acrylate, 2-methyl-2-adamantyl acrylate, t-butyl methacrylate, methoxymethyl methacrylate, ethoxymethyl methacrylate, 2-methyl-2-adamantyl methacrylate, t-butyl-α-trifluoromethyl acrylate, methoxymethyl-α-trifluoromethyl acryl ate, ethoxymethyl-α-trifluoro methyl acrylate and 2-methyl-2-adamantyl-α-trifluoromethyl acrylate.

Although the chemically amplified resist material used in Embodiment 4 is composed of the base polymer and the dissolution inhibitor both of which generate carboxylic acid through irradiation with light, a chemically amplified resist material in which a base polymer alone generates carboxylic acid through irradiation with light can be used instead.

Embodiment 5

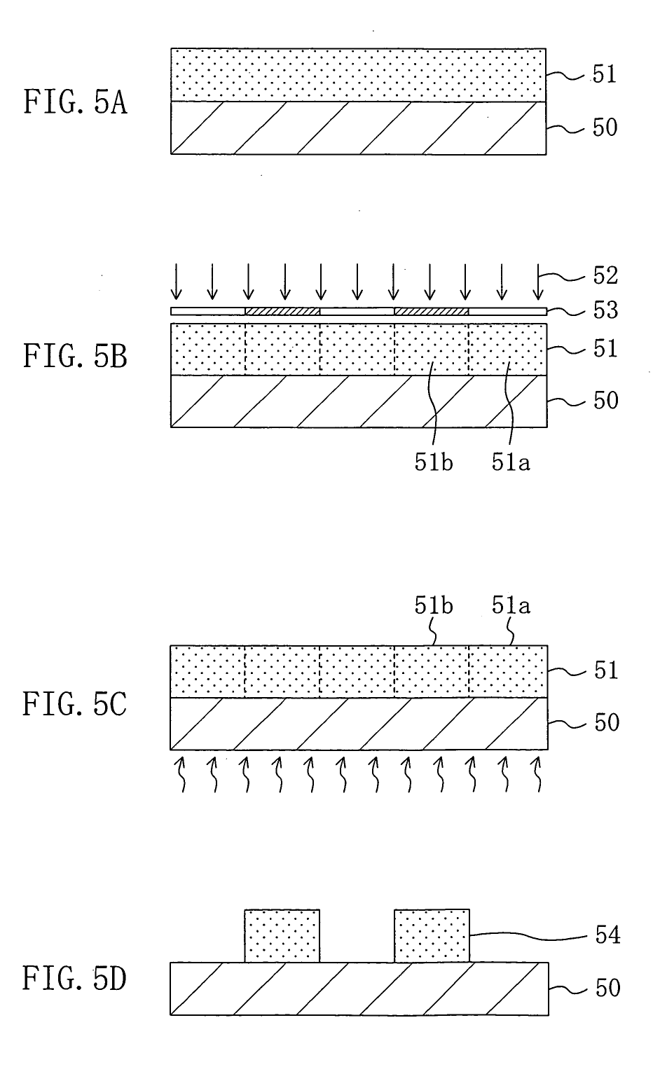

A pattern formation method according to Embodiment 5 of the invention will now be described with reference to FIGS. 5A through 5D.

First, a positive chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 40 mol %:60 mol %) | | |
| Dissolution inhibitor: 2-methyl-2-adamantyl methacrylate | 0.30 | g |
| Acid generator: N-(trifluoromethylsulfonyloxy)succinimide | 0.035 | g |
| Solvent: propylene glycol monomethyl ether acetate | 20 | g |

Next, as shown in FIG. 5A, the aforementioned chemically amplified resist material is applied on a substrate 50 so as to form a resist film 51 with a thickness of 0.35 μm.

Then, as shown in FIG. 5B, pattern exposure is carried out by irradiating the resist film 51 with KrF excimer laser 52 with NA of 0.92 through a photomask 53. In this case, since the NA is 0.92, the exposing light of the KrF excimer laser 52 has a light component entering the resist film 51 at the Brewster's angle.

Thereafter, as shown in FIG. 5C, the substrate 50 is baked with a hot plate at a temperature of 100° C. for 60 seconds. Thus, an exposed portion 51a of the resist film 51 becomes soluble in an alkaline developer because an acid is generated from the acid generator therein while an unexposed portion 51b of the resist film 51 remains insoluble in an alkaline developer because no acid is generated from the acid generator therein.

Next, the resultant resist film 51 is developed with a 2.38 wt % tetramethylammonium hydroxide developer (alkaline developer). In this manner, a resist pattern 54 made of the unexposed portion 51b of the resist film 51 and having a line width of 0.13 μm can be formed in a good shape as shown in FIG. 5D.

In Embodiment 5, when the resist film 51 is irradiated with the exposing light of the KrF excimer laser 52, carboxylic acid, that is, a strong acid, is generated from the dissolution inhibitor in the exposed portion 51a of the resist film 51. Accordingly, the dissolving rate of the exposed portion 51a of the resist film 51 can be increased, so that the solubility contrast of the resist film 51 can be improved.

As a result, according to Embodiment 5, the lowering of the contrast of the exposing light derived from the polarization effect caused through irradiation with the exposing light having a light component entering the resist film 51 at the Brewster's angle can be compensated by the improved solubility contrast of the resist film 51, so that the resist pattern 54 can be formed in a good shape.

The dissolution inhibitor used in Embodiment 5 for generating carboxylic acid through irradiation with light may be an ester of acrylic acid, methacrylic acid or α-trifluoromethyl acrylic acid. Specific examples, which do not limit the invention, are t-butyl acrylate, methoxymethyl acrylate, ethoxymethyl acrylate, 2-methyl-2-adamantyl acrylate, t-butyl methacrylate, methoxymethyl methacrylate, ethoxymethyl methacrylate, 2-methyl-2-adamantyl methacrylate, t-butyl-α-trifluoromethyl acrylate, methoxymethyl-α-trifluoromethyl acrylate, ethoxymethyl-α-trifluoromethyl acrylate and 2-methyl-2-adamantyl-α-trifluoromethyl acrylate.

Embodiment 6

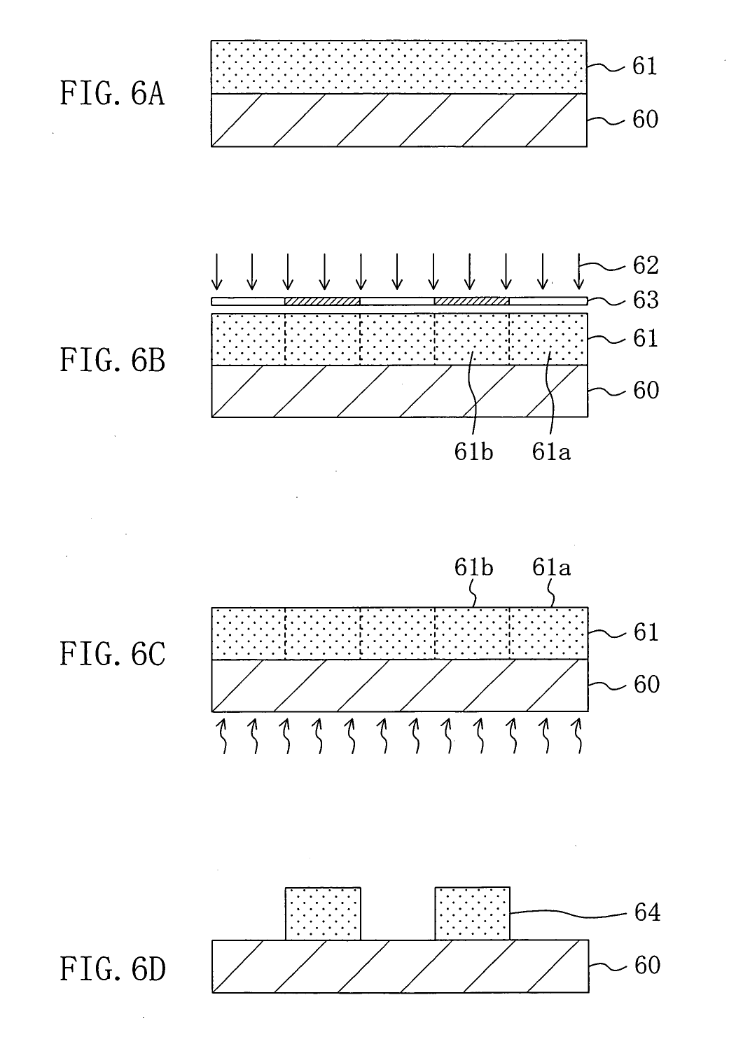

A pattern formation method according to Embodiment 6 of the invention will now be described with reference to FIGS. 6A through 6D.

First, a positive chemically amplified resist material having the following composition is prepared:

| | | |
|---|---|---|
| Base polymer: poly((t-butoxycarbonyloxysulfonylstyrene) - | 2 | g |
| (styrenesulfonic acid)) | | |
| (wherein t-butoxycarbonyloxysulfonylstyrene:styrenesulfonic | | |
| acid = 30 mol %:70 mol %) | | |
| Dissolution inhibitor: styrenesulfonic acid-t-butyl ester | 0.30 | g |
| Acid generator: N-(trifluoromethylsulfonyloxy) succinimide | 0.035 | g |
| Solvent: propylene glycol monomethyl ether acetate | 20 | g |

Next, as shown in FIG. 6A, the aforementioned chemically amplified resist material is applied on a substrate 60 so as to form a resist film 61 with a thickness of 0.4 μm.

Then, as shown in FIG. 6B, pattern exposure is carried out by irradiating the resist film 61 with KrF excimer laser 62 with NA of 0.92 through a photomask 63. In this case, since the NA is 0.92, the exposing light of the KrF excimer laser 62 has a light component entering the resist film 61 at the Brewster's angle.

Thereafter, as shown in FIG. 6C, the substrate 60 is baked with a hot plate at a temperature of 110° C. for 60 seconds. Thus, an exposed portion 61a of the resist film 61 becomes soluble in an alkaline developer because an acid is generated from the acid generator therein while an unexposed portion 61b of the resist film 61 remains insoluble in an alkaline developer because no acid is generated from the acid generator therein.

Next, the resultant resist film 61 is developed with a 2.38 wt % tetramethylammonium hydroxide developer (alkaline developer). In this manner, a resist pattern 64 made of the unexposed portion 61b of the resist film 61 and having a line width of 0.13 μm can be formed in a good shape as shown in FIG. 6D.

In Embodiment 6, when the resist film 61 is irradiated with the exposing light of the KrF excimer laser 62, sulfonic acid, that is, a strong acid, is generated from the base polymer and the dissolution inhibitor in the exposed portion 61a of the resist film 61. Accordingly, the dissolving rate of the exposed portion 61a of the resist film 61 can be increased, so that the solubility contrast of the resist film 61 can be improved.

As a result, according to Embodiment 6, the lowering of the contrast of the exposing light derived from the polarization effect caused through irradiation with the exposing light having a light component entering the resist film 61 at the Brewster's angle can be compensated by the improved solubility contrast of the resist film 61, so that the resist pattern 64 can be formed in a good shape.

The base polymer used in Embodiment 6 for generating sulfonic acid through irradiation with light may be an ester of polyvinylsulfonic acid, polystyrenesulfonic acid or polynorbornenesulfonic acid. Specific examples, which do not limit the invention, are poly(styrenesulfonic acid-t-butyl ester), poly(styrenesulfonic acid-2-methyl-2-adamantyl ester), poly(norbornenesulfonic acid-t-butyl ester) and poly(norbornenesulfonic acid-2-methyl-2-adamantyl ester).

Also, the dissolution inhibitor for generating sulfonic acid through irradiation with light may be an ester of vinylsulfonic acid, styrenesulfonic acid or norbornenesulfonic acid. Specific examples, which do not limit the invention, are styrenesulfonic acid-t-butyl ester, styrenesulfonic acid-2-methyl-2-adamantyl ester, norbornenesulfonic acid-t-butyl ester and norbornenesulfonic acid-2-methyl-2-adamantyl ester.

Although the chemically amplified resist material used in Embodiment 6 is composed of the base polymer and the dissolution inhibitor both of which generate sulfonic acid through irradiation with light, a chemically amplified resist material in which a base polymer alone generates sulfonic acid through irradiation with light may be used instead.

Embodiment 7

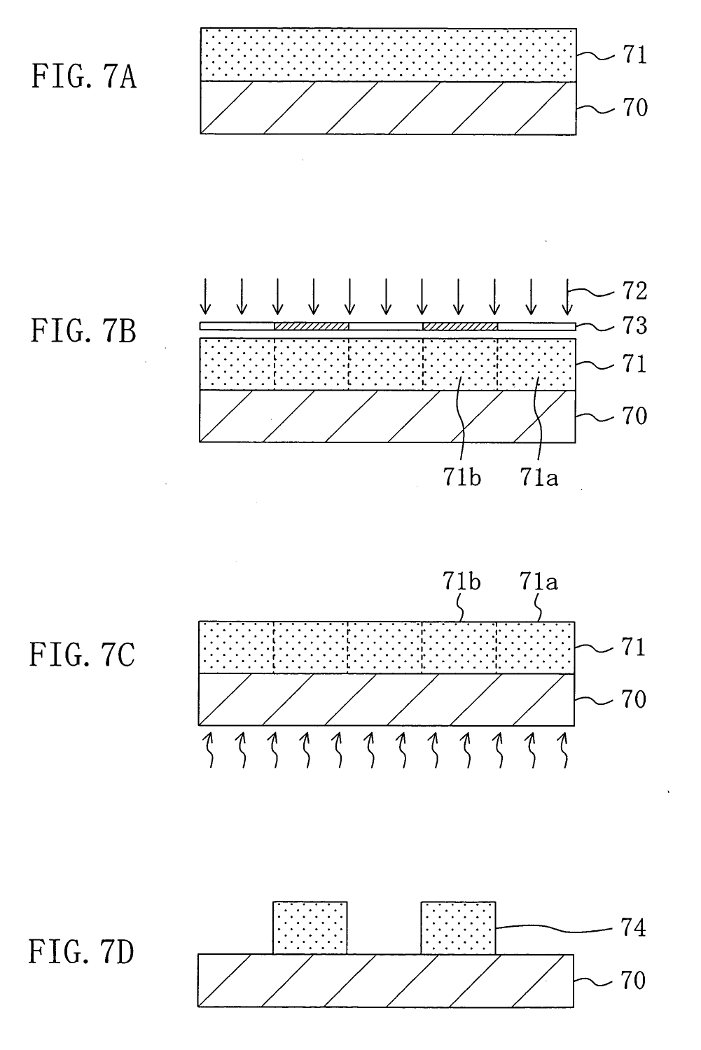

A pattern formation method according to Embodiment 7 of the invention will now be described with reference to FIGS. 7A through 7D.

First, a positive chemically amplified resist material having the following composition is prepared:

| | | |
|---|---|---|
| Base polymer: poly((t-butoxycarbonyloxystyrene) - | 2 | g |
| (hydroxystyrene))(wherein | | |
| t-butoxycarbonyloxystyrene:hydroxystyrene = | | |
| 30 mol %:70 mol %) | | |
| Dissolution inhibitor: styrenesulfonic acid-t-butyl ester | 0.30 | g |
| Acid generator: N-(trifluoromethylsulfonyloxy)succinimide | 0.035 | g |
| Solvent: propylene glycol monomethyl ether acetate | 20 | g |

Next, as shown in FIG. 7A, the aforementioned chemically amplified resist material is applied on a substrate 70 so as to form a resist film 71 with a thickness of 0.4 μm.

Then, as shown in FIG. 7B, pattern exposure is carried out by irradiating the resist film 71 with KrF excimer laser 72 with NA of 0.92 through a photomask 73. In this case, since the NA is 0.92, the exposing light of the KrF excimer laser 72 has a light component entering the resist film 71 at the Brewster's angle.

Thereafter, as shown in FIG. 7C, the substrate 70 is baked with a hot plate at a temperature of 100° C. for 60 seconds. Thus, an exposed portion 71a of the resist film 71 becomes soluble in an alkaline developer because an acid is generated from the acid generator therein while an unexposed portion 71b of the resist film 71 remains insoluble in an alkaline developer because no acid is generated from the acid generator therein.

Next, the resultant resist film 71 is developed with a 2.38 wt % tetramethylammonium hydroxide developer (alkaline developer). In this manner, a resist pattern 74 made of the unexposed portion 71b of the resist film 71 and having a line width of 0.13 μm can be formed in a good shape as shown in FIG. 7D.

In Embodiment 7, when the resist film 71 is irradiated with the exposing light of the KrF excimer laser 72, sulfonic acid, that is, a strong acid, is generated from the dissolution inhibitor in the exposed portion 71a of the resist film 71. Accordingly, the dissolving rate of the exposed portion 71a of the resist film 71 can be increased, so that the solubility contrast of the resist film 71 can be improved.

As a result, according to Embodiment 7, the lowering of the contrast of the exposing light derived from the polarization effect caused through irradiation with the exposing light having a light component entering the resist film 71 at the Brewster's angle can be compensated by the improved solubility contrast of the resist film 71, so that the resist pattern 74 can be formed in a good shape.

The dissolution inhibitor used in Embodiment 7 for generating sulfonic acid through irradiation with light may be an ester of vinylsulfonic acid, styrenesulfonic acid or norbornenesulfonic acid. Specific examples, which do not limit the invention, are styrenesulfonic acid-t-butyl ester, styrenesulfonic acid-2-methyl-2-adamantyl ester, norbornenesulfonic acid-t-butyl ester and norbornenesulfonic acid-2-methyl-2-adamantyl ester.

Embodiment 8

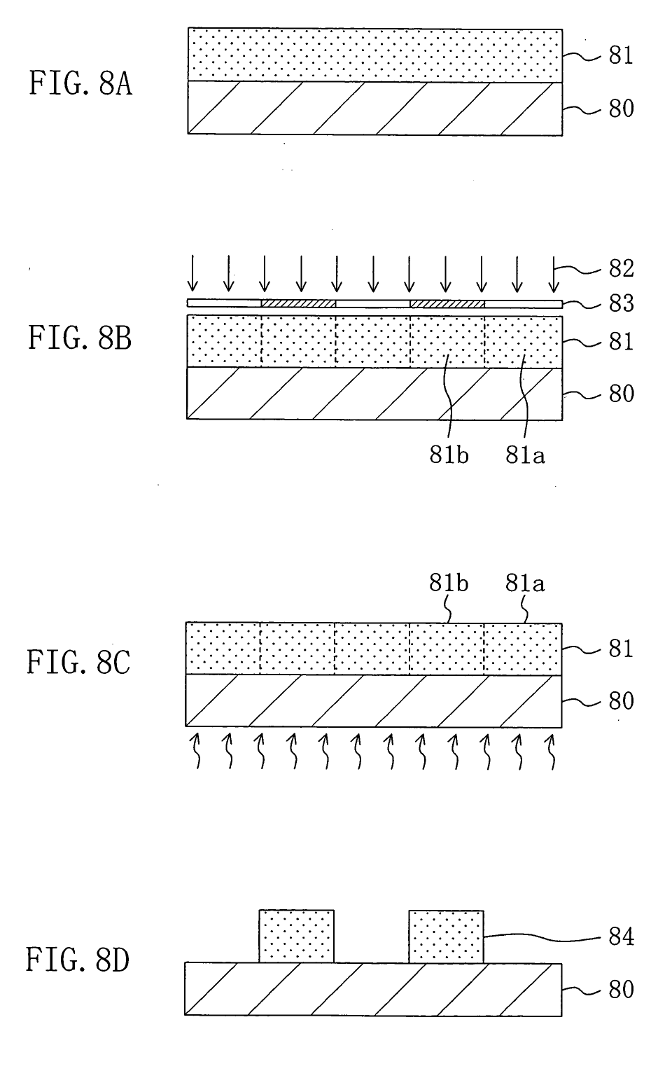

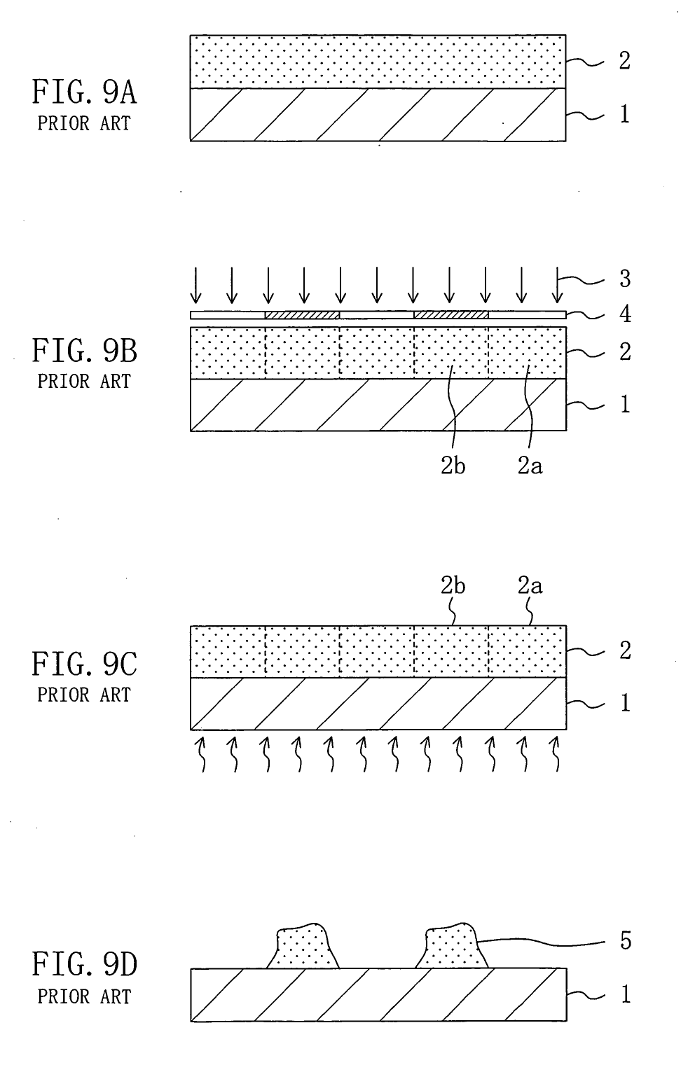

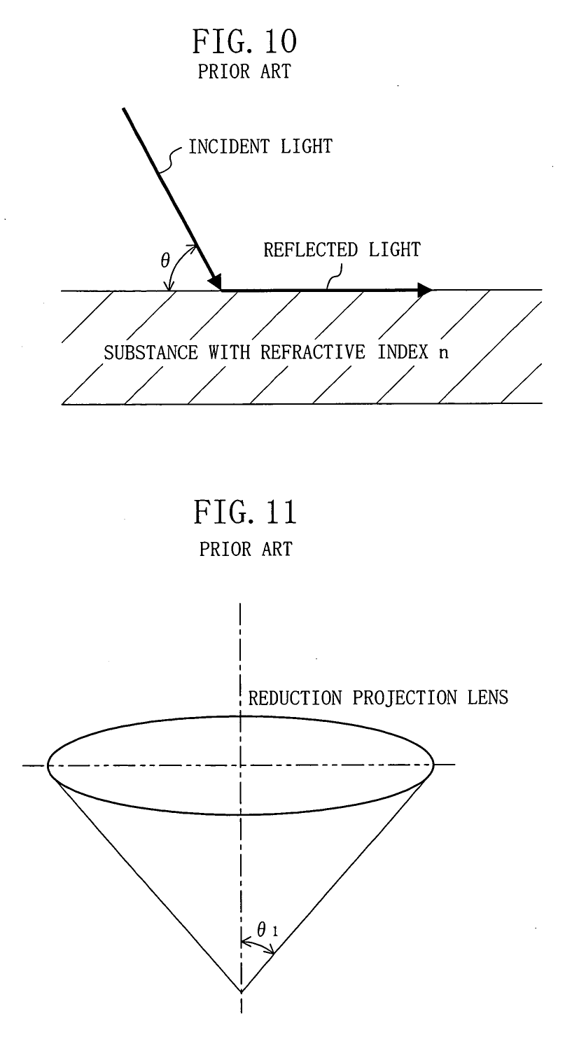

A pattern formation method according to Embodiment 8 of the invention will now be described with reference to FIGS. 8A through 8D.

First, a positive chemically amplified resist material having the following composition is prepared:

| | | |
|---|---|---|
| Base polymer: poly((t-butoxycarbonyloxystyrene) - | 2 | g |
| (hydroxystyrene)) (wherein | | |
| t-butoxycarbonyloxystyrene:hydroxystyrene = | | |
| 35 mol %:65 mol %) | | |
| Acid generator: N-(trifluoromethylsulfonyloxy)phthalimide | 0.04 | g |
| Acid: acetic acid | 0.05 | g |
| Solvent: propylene glycol monomethyl ether acetate | 20 | g |

Next, as shown in FIG. 8A, the aforementioned chemically amplified resist material is applied on a substrate 80 so as to form a resist film 81 with a thickness of 0.4 μm.

Then, as shown in FIG. 8B, pattern exposure is carried out by irradiating the resist film 81 with KrF excimer laser 82 with NA of 0.92 through a photomask 83. In this case, since the NA is 0.92, the exposing light of the KrF excimer laser 82 has a light component entering the resist film 81 at the Brewster's angle.

Thereafter, as shown in FIG. 8C, the substrate 80 is baked with a hot plate at a temperature of 105° C. for 60 seconds. Thus, an exposed portion 81a of the resist film 81 becomes soluble in an alkaline developer because an acid is generated from the acid generator therein while an unexposed portion 81b of the resist film 81 remains insoluble in an alkaline developer because no acid is generated from the acid generator therein.

Next, the resultant resist film 81 is developed with a 2.38 wt % tetramethylammonium hydroxide developer (alkaline developer). In this manner, a resist pattern 84 made of the unexposed portion 81b of the resist film 81 and having a line width of 0.13 μm can be formed in a good shape as shown in FIG. 8D.

In Embodiment 8, since the chemically amplified resist material includes the acid, when the resist film 81 is irradiated with the exposing light of the KrF excimer laser 82, the dissolving rate of the exposed portion 81a of the resist film 81 can be increased, so that the solubility contrast of the resist film 81 can be improved.

As a result, according to Embodiment 8, the lowering of the contrast of the exposing light derived from the polarization effect caused through irradiation with the exposing light having a light component entering the resist film 81 at the Brewster's angle can be compensated by the improved solubility contrast of the resist film 81, so that the resist pattern 84 can be formed in a good shape.

Although acetic acid is used as the acid included in the chemically amplified resist material in Embodiment 8, acrylic acid or formic acid can be used instead.

Furthermore, in each of Embodiments 1 through 8, any of KrF excimer laser (of a wavelength of a 248 nm band), ArF excimer laser (of a wavelength of a 193 nm band), Xe₂ laser (of a wavelength of a 172 nm band), F₂ laser (of a wavelength of a 157 nm band), Kr₂ laser (of a wavelength of a 146 nm band), ArKr laser (of a wavelength of a 134 nm band), Ar₂ laser (of a wavelength of a 126 nm band) and extreme UV (of a wavelength of a 13, 11 or 5 nm band) can be appropriately used as the exposing light.

Although the NA of the exposing light is 0.92 in each of Embodiments 1 through 8, the NA employed in the invention is not limited to 0.92 but the present invention is applicable to irradiation with exposing light having a light component that enters a resist film at the Brewster's angle. The exposing light having a light component that enters a resist film at the Brewster's angle generally has NA of 0.9 or more.

What is claimed is:

1. A pattern formation method comprising the steps of:
forming a resist film of a chemically amplified resist material; and
forming a resist pattern by developing said resist film with a developer after irradiating, through a mask, said resist film with exposing light having a light component entering said resist film at the Brewster's angle,
wherein a thickness reduction ratio of said resist pattern to said resist film is 5% or less.

2. The pattern formation method of claim 1,
wherein said chemically amplified resist material is a positive type, and
a protection ratio that is a ratio of a polymer protected by a protecting group in an alkali-soluble polymer included in said chemically amplified resist material is 50% or more.

3. The pattern formation method of claim 2,
wherein said protecting group is a t-butyl group or a t-butyloxycarbonyl group.

4. The pattern formation method of claim 2,
wherein said chemically amplified resist material is a positive type, and
an acid generator included in said chemically amplified resist material is an onium salt.

5. The pattern formation method of claim 4,
wherein said onium salt is triphenylsulfonium trifluoromethanesulfonic acid, triphenylsulfonium nonafluorobutanesulfonic acid or diphenyliodonium trifluoromethanesulfonic acid.

6. The pattern formation method of claim 1,
wherein said chemically amplified resist material is a positive type, and
the pattern formation method further comprises, between the step of forming a resist film and the step of forming a resist pattern, a step of forming, in a surface portion of said resist film, an insoluble layer that is insoluble in said developer.

7. The pattern formation method of claim 6,
wherein said insoluble layer is formed by supplying an alkaline aqueous solution onto said resist film.

8. The pattern formation method of claim 7,
wherein said alkaline aqueous solution is a tetramethylammonium hydroxide aqueous solution, a tetraethylammonium hydroxide aqueous solution, a tetra-n-butylammonium hydroxide aqueous solution or a choline aqueous solution.

9. The pattern formation method of claim 1,
wherein said exposing light is UV, KrF excimer laser, ArF excimer laser, F₂ laser, ArKr laser, Ar₂ laser, Kr₂ laser or extreme UV.

10. A pattern formation method comprising the steps of:
forming a resist film of a positive chemically amplified resist material; and
forming a resist pattern by developing said resist film with a developer after irradiating, through a mask, said resist film with exposing light having a light component entering said resist film at the Brewster's angle,
wherein said chemically amplified resist material includes a base polymer for generating acid through irradiation with light.

11. The pattern formation method of claim 10,
wherein said acid is carboxylic acid or sulfonic acid.

12. The pattern formation method of claim 10,
wherein said chemically amplified resist material includes a dissolution inhibitor for generating acid through irradiation with light.

13. The pattern formation method of claim 12,
wherein said acid is carboxylic acid or sulfonic acid.

14. The pattern formation method of claim 10,
wherein said acid is acrylic acid, methacrylic acid, α-trifluoromethylacrylic acid, vinylsulfonic acid or styrenesulfonic acid.

15. The pattern formation method of claim 10,
wherein said exposing light is UV, KrF excimer laser, ArF excimer laser, F₂ laser, ArKr laser, Ar₂ laser, Kr₂ laser or extreme V.

16. A pattern formation method comprising the steps of:
forming a resist film of a positive chemically amplified resist material; and
forming a resist pattern by developing said resist film with a developer after irradiating, through a mask, said resist film with exposing light having a light component entering said resist film at the Brewster's angle,
wherein said chemically amplified resist material includes a dissolution inhibitor for generating acid through irradiation with light.

17. The pattern formation method of claim 16,
wherein said acid is carboxylic acid or sulfonic acid.

18. The pattern formation method of claim 16,
wherein said acid is acrylic acid, methacrylic acid, α-trifluoromethylacrylic acid, vinylsulfonic acid or styrenesulfonic acid.

19. The pattern formation method of claim 15,
wherein said exposing light is UV, KrF excimer laser, ArF excimer laser, F₂ laser, ArKr laser, Ar₂ laser, Kr₂ laser or extreme V.

20. A pattern formation method comprising the steps of:
forming a resist film of a positive chemically amplified resist material; and
forming a resist pattern by developing said resist film with a developer after irradiating, through a mask, said resist-film with exposing light having a light component entering said resist film at the Brewster's angle,
wherein said chemically amplified resist material includes an acid

21. The pattern formation method of claim 20,
wherein said acid is acetic acid, acrylic acid or formic acid.

22. The pattern formation method of claim 20,
wherein said exposing light is UV, KrF excimer laser, ArF excimer laser, F₂ laser, ArKr laser, Ar₂ laser, Kr₂ laser or extreme UV.
